(19) United States
(12) Patent Application Publication
(10) Pub. No.: US 2014/0167576 A1
(43) Pub. Date: Jun. 19, 2014

(54) SERVER CHASSIS

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventor: XIAN-XIU TANG, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 13/723,217

(22) Filed: Dec. 21, 2012

(30) Foreign Application Priority Data
Dec. 13, 2012 (CN) 201210536762.4

(51) Int. Cl. H05K 7/14

(52) U.S. Cl. CPC H05K 7/1489
USPC 312/223.1

(57) ABSTRACT

A server chassis includes an enclosure, two slide members, and a number of positioning members. The enclosure includes two opposite sidewalls. An end of each sidewall defines a slide slot extending along a lengthwise direction of the sidewall. The slide members each define a number of through holes aligning with the corresponding slide slot. The positioning members are respectively extended through the through holes and the corresponding slide slots, to slidably mount the slide members to the sidewalls.

### BACKGROUND

1. Technical Field

The present disclosure relates to a server chassis.

2. Description of Related Art

A server chassis is installed in a server cabinet with particular size suitable for the server chassis. Because a server cabinet cannot be adjusted in size easily, an adjustable server chassis would be desirable in order to be accommodated in the server cabinet.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric view of an exemplary embodiment of a server chassis.

FIG. 2 is a partial, enlarged, exploded view of FIG. 1.

FIG. 3 is similar to FIG. 2, but viewed from another perspective.

FIG. 4 is an enlarged view of the circled portion IV of FIG. 1.

FIG. 5 is similar to FIG. 4, but shows a different state.

FIG. 6 is an assembled, isometric view of the server chassis of FIG. 1 together with a first server cabinet.

FIG. 7 is an assembled, isometric view of the server chassis of FIG. 1 together with a second server cabinet.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

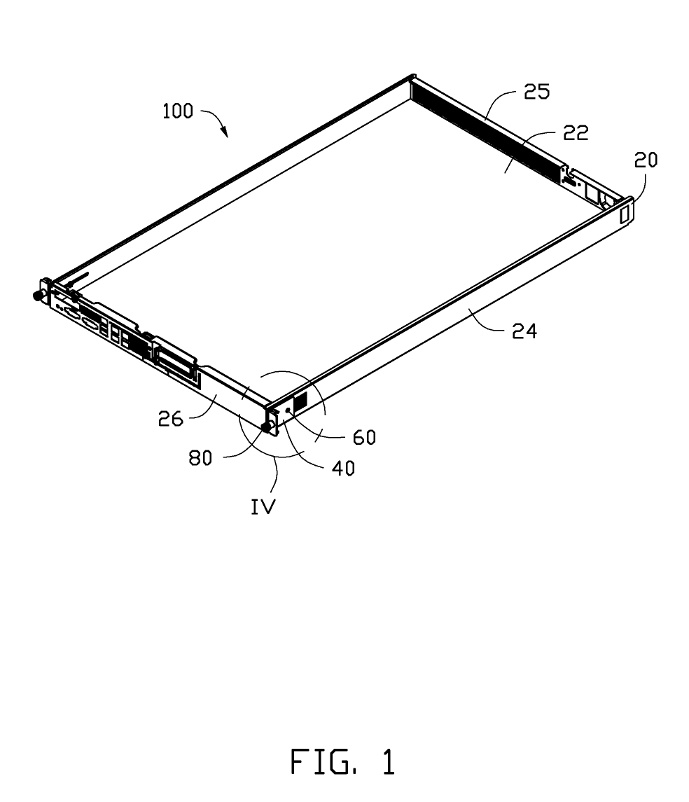

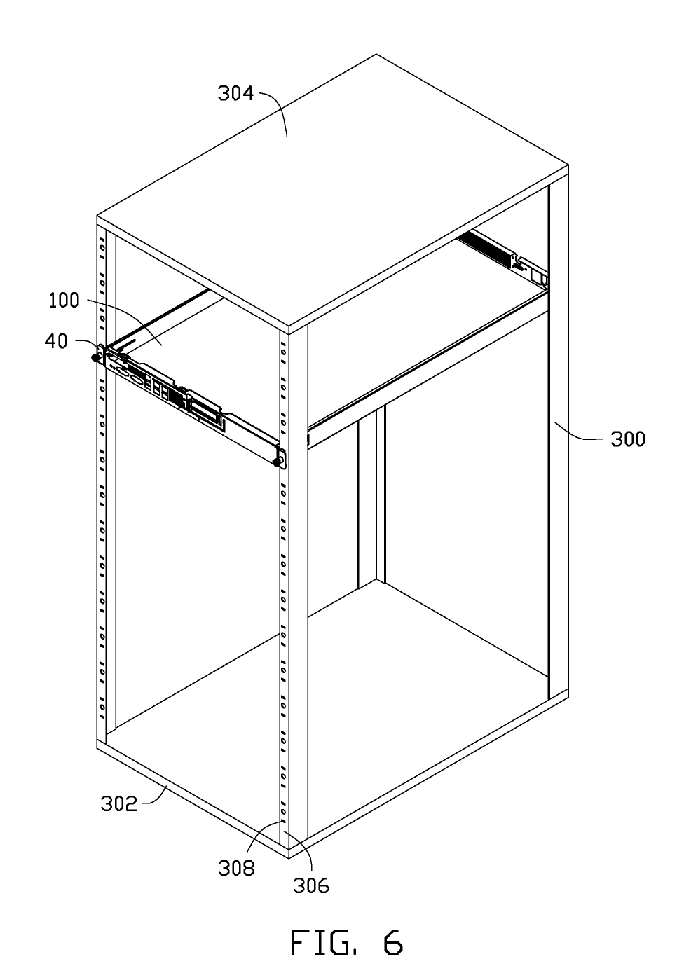

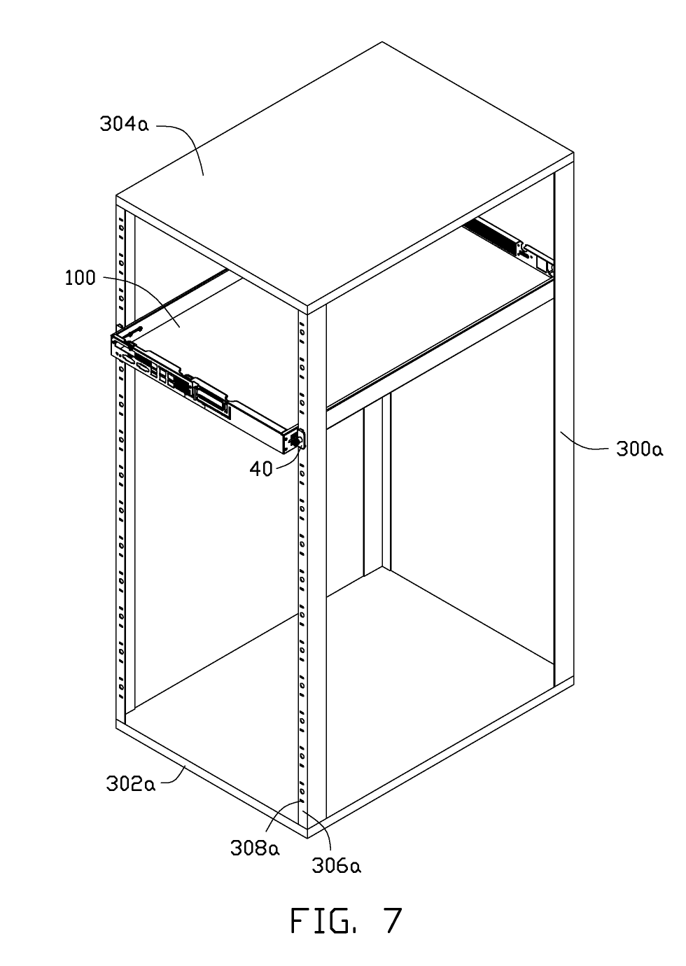

FIG. 1 shows an exemplary embodiment of a server chassis 100 that can be installed in either a first server cabinet 300 (shown in FIG. 6) or a second server cabinet 300a (shown in FIG. 7). The length of the first server cabinet 300 is greater than the length of the second server cabinet 300a. The server chassis 100 includes an enclosure 20, two slide members 40, four positioning members 60, and two fasteners 80.

The enclosure 20 includes a rectangular bottom wall 22, two sidewalls 24 perpendicularly extending up from two opposite sides of the bottom wall 22, a front end wall 25 perpendicularly extending up from a front end of the bottom wall 22 and connected between front ends of the sidewalls 24, and a rear end wall 26 perpendicularly extending up from a rear end of the bottom wall 22 and connected between rear ends of the sidewalls 24.

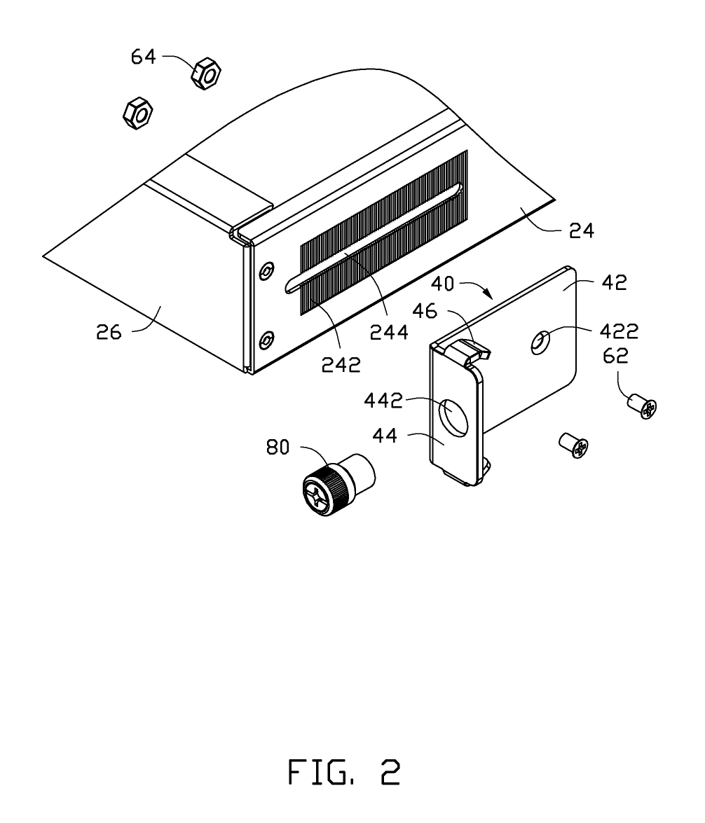

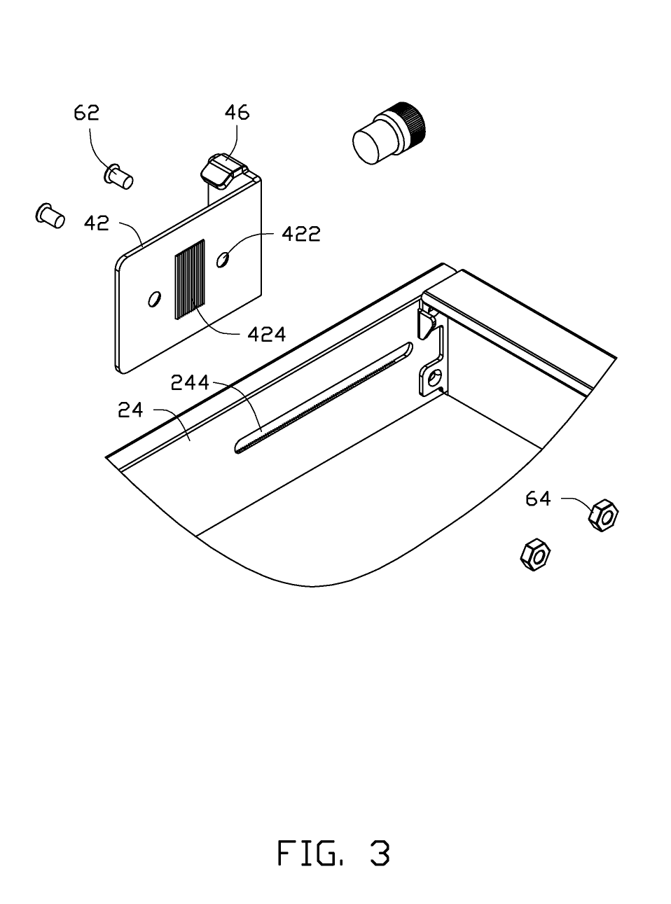

FIG. 2 and FIG. 3 show that the rear end of each sidewall 24 defines a slide slot 244 and forms a gear rack 242. The slide slot 244 extends along a lengthwise direction of the sidewall 244, adjacent to the rear end wall 26. The gear rack 242 extends along the lengthwise direction of the sidewall 244, adjacent to the rear end wall 26. The slide slot 244 is located in a middle of the gear rack 242.

Each slide member 40 is substantially L-shaped, and includes a movable plate 42, a positioning plate 44 perpendicularly extending out from a rear end of the movable plate 42, and two hooks 46 respectively extending forward from top and bottom ends of the positioning plate 44. A middle of the movable plate 42 defines two spaced through holes 422 located in a line along a lengthwise direction of the movable plate 42. A plurality of teeth 424 protrudes in from the movable plate 422, between the through holes 422. The teeth 424 are capable of meshing with the gear rack 242. A middle of the positioning plate 44 defines a mounting hole 442.

In the embodiment, each positioning member 60 includes a screw 62 and a nut 64.

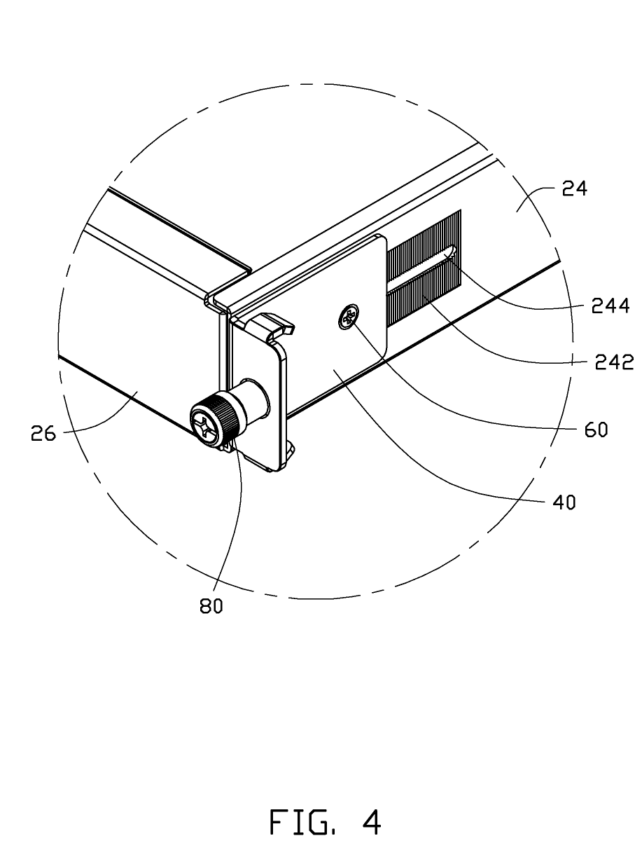

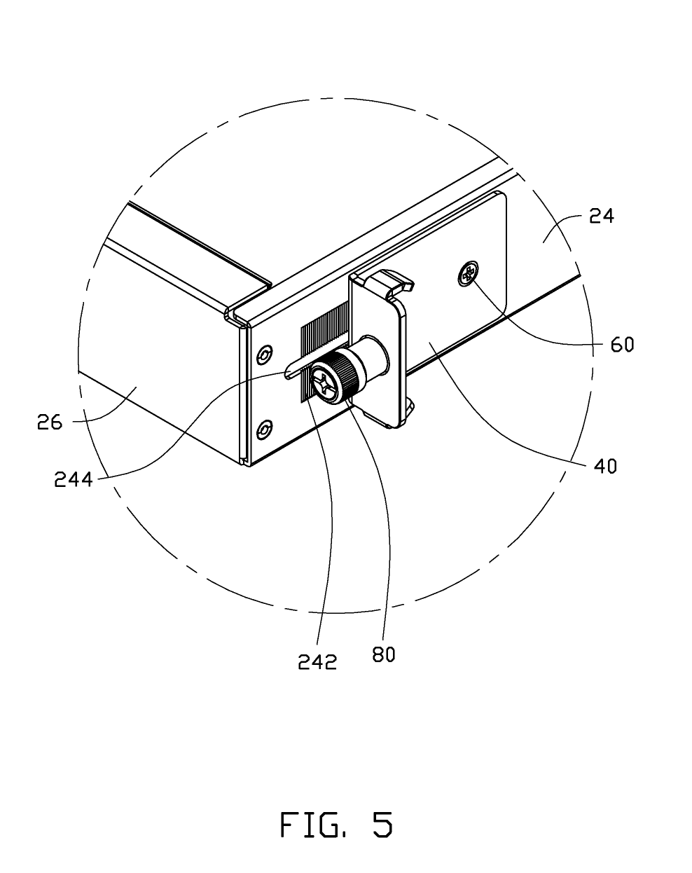

FIG. 4 and FIG. 5 show that in assembly of the server chassis 100. The teeth 424 of each slide member 42 is meshed with the corresponding gear rack 242, with the positioning plates 44 located adjacent to the rear end wall 26. The through holes 422 are aligned with the corresponding slide slot 244. The screws 62 extend through the through holes 422 and the corresponding slide slot 244, to be screwed to the nuts 64, respectively. The nuts 64 are abutted against inner surfaces of the sidewall 24. Therefore, the slide members 40 are slidably mounted to the corresponding sidewall 24s, with the screws 62 slidable along the corresponding slide slots 244.

FIG. 6 shows that the first server cabinet 300 includes a base 302, a top wall 304, and four support poles 306 respectively connected between four corners of the base 302 and the top wall 304. Two opposite support poles 306 positioned in a rear end of the first server cabinet 300 respectively define a plurality of latching holes 308 arrayed in a lengthwise direction of the corresponding support pole 306. In assembly of the server chassis 100 to the first server cabinet 300, the screws 62 are released, thereby the slide members 40 are able to slide along the corresponding slide slots 244, and the screws 62 is slid in the slide slots 244, until the positioning plates 44 of the slide members 40 suit for the length of the first server cabinet 300. The screws 62 are screwed back to allow the teeth 424 to mesh with the corresponding gear racks 242, and the slide members 40 are mounted on the sidewalls 24. The server chassis 100 is inserted into the first server cabinet 300 from the rear end of the server cabinet 300, until the hooks 46 of the slide members 40 are latched into the corresponding latching holes 308. The fasteners 80 respectively extend through the mounting holes 442, to be fixed to the rear support poles 306.

FIG. 7 shows that the second server cabinet 300a includes a base 302a, a top wall 304a, and four support poles 306a respectively connected between four corners of the base 302a and the top wall 304a. Two opposite support poles 306a located in a rear end of the second server cabinet 300a respectively define a plurality of latching holes 308a arrayed in a lengthwise direction of the corresponding support pole 306a. In assembly of the server chassis 100 to the second server cabinet 300a, the screws 62 are released, thereby the slide members 40 are able to slide along the corresponding slide slots 244, with the screws 62 sliding in the slide slots 244, until the slide members 40 match the length of the second server cabinet 300a. The screws 62 are screwed back to allow the teeth 424 to mesh with the corresponding gear rack 242. The server chassis 100 is inserted into the second server cabinet 300a from the rear end of the server cabinet 300a, unit the hooks 46 of the slide members 40 are latched into the corresponding latching holes 308a. The fasteners 80 respectively extend through the mounting holes 442, to be fixed to the rear support poles 306a.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A server chassis, comprising:
an enclosure comprising two opposite sidewalls, wherein an end of each sidewall defines a slide slot extending along a lengthwise direction of the sidewall;
two slide members each defining a plurality of through holes; and
a plurality of positioning members respectively extended through the through holes and the slide slots, to slidably mount the slide members to the sidewalls.

2. The server chassis of claim 1, wherein each sidewall comprises a gear rack adjacent to a corresponding one of the slide slot and extending along the lengthwise direction of the sidewall, each slide member comprises a plurality of teeth meshing with the corresponding gear rack.

3. The server chassis of claim 2, wherein the slide slots are respectively located in middles of the corresponding gear racks.

4. The server chassis of claim 2, wherein each slide member comprises a movable plate, a positioning plate extending out from an end of the movable plate, and a hook extending from the positioning plate to be latched into a server cabinet, the through holes are defined in the movable plate, the plurality of teeth protrude in from the movable plate.

5. The server chassis of claim 1, wherein each positioning member comprises a screw and a nut, the screw extends through the corresponding through hole and the corresponding slide slot, to be screwed to the nut, the nut abuts against an inner surface of the corresponding sidewall.

6. A server chassis, comprising:
an enclosure comprising two opposite sidewalls; and
two slide members slidably mounted to front ends of the sidewalls, respectively, in a fore-and-aft direction, each slide member comprising a positioning plate perpendicular to the corresponding sidewall to be fixed to a rear support pole of a server cabinet.

7. The server chassis of claim 6, wherein each sidewall comprises a gear rack extending along the fore-and-aft direction of the sidewall, each slide member comprises a plurality of teeth meshing with the corresponding gear rack.

8. The server chassis of claim 6, wherein each sidewall defines a slide slot in the fore-and-aft direction of the sidewall, a fastener extends through each slide member and slidably engages in the slide slot of the corresponding sidewall.
